(19) United States
(12) Patent Application Publication
(10) Pub. No.: US 2023/0269929 A1
(43) Pub. Date: Aug. 24, 2023

(54) SEMICONDUCTOR DEVICE AND METHOD FOR FABRICATING THE SAME

(71) Applicant: SK hynix Inc., Gyeonggi-do (KR)

(72) Inventors: Dong Il SONG, Gyeonggi-do (KR); Seung Hwan Kim, Gyeonggi-do (KR)

(21) Appl. No.: 17/974,092

(22) Filed: Oct. 26, 2022

(30) Foreign Application Priority Data
Feb. 18, 2022 (KR) 10-2022-0021498

(51) Int. Cl. H01L 27/108; G11C 5/06

(52) U.S. Cl. CPC H01L 27/10805; H01L 27/10897; G11C 5/063

(57) ABSTRACT

A semiconductor device includes: a lower structure; an active layer over the lower structure; a bit line coupled to one side of the active layer and extending vertically from the lower structure; a data storage element coupled to another side of the active layer; a word line disposed adjacent to the active layer and extending in a direction crossing the active layer; and a capping layer disposed between the word line and the data storage element and including a trap-suppressing material in contact with the active layer.

### CROSS-REFERENCE TO RELATED APPLICATIONS

The present application claims priority of Korean Patent Application No. 10-2022-0021498, filed on Feb. 18, 2022, which is incorporated herein by reference in its entirety.

### BACKGROUND

### 1. Field

Exemplary embodiments of the present invention relate to a semiconductor device, and more particularly, to a semiconductor device of a three-dimensional structure, and a method for fabricating the same.

### 2. Description of the Related Art

The size of a memory cell is being continuously reduced to increase the net die of a memory device. As the size of memory cells is miniaturized, it is required to reduce parasitic capacitance and increase the capacitance as well. However, it is difficult to increase the net die due to the structural limitation of the memory cells.

Recently, three-dimensional semiconductor memory devices including memory cells that are arranged in three dimensions are being suggested.

### SUMMARY

Embodiments of the present invention are directed to a semiconductor device including highly integrated memory cells, and a method for fabricating the same.

In accordance with an embodiment of the present invention, a semiconductor device may include: a lower structure; an active layer over the lower structure; a bit line coupled to one side of the active layer and extending vertically from the lower structure; a data storage element coupled to another side of the active layer; a word line disposed adjacent to the active layer and extending in a direction crossing the active layer; and a capping layer disposed between the word line and the data storage element and including a trap-suppressing material in contact with the active layer.

In accordance with another embodiment of the present invention, A semiconductor device may include: a lower structure; an active layer over the lower structure; a bit line coupled to one side of the active layer and extending vertically from the lower structure; a capacitor coupled to another side of the active layer; a word line disposed adjacent to the active layer and extending in a direction crossing the active layer; a first capping layer disposed between the word line and the capacitor and including a first trap-suppressing material in contact with the active layer; and a second capping layer disposed between the bit line and the word line and including a second trap-suppressing material in contact with the active layer, Each of the first and second trap-suppressing materials may include a nitrogen-free material. Each of the first and second trap-suppressing materials may include silicon oxide.

These and other features and advantages of the present invention shall become apparent to the person having ordinary skill in the art from the following detailed description of the invention in reference to the accompanying drawings.

### BRIEF DESCRIPTION OF THE DRAWINGS

FIG. 1 is a schematic perspective view illustrating a semiconductor device in accordance with an embodiment of the present invention.

FIG. 2A is a schematic cross-sectional view illustrating a semiconductor device in accordance with an embodiment of the present invention.

FIG. 2B is a cross-sectional view illustrating a memory cell.

FIG. 2C is a schematic cross-sectional view illustrating a memory cell in accordance with another embodiment of the present invention,

FIGS. 3 to 16 are cross-sectional views illustrating a method for fabricating a semiconductor device in accordance with an embodiment of the present invention.

### DETAILED DESCRIPTION

Embodiments of the present invention will be described below with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily drawn to scale and in some instances, proportions may have been exaggerated in order to clearly illustrate certain features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

According to the following embodiments of the present invention, it is possible to increase the memory cell density and reduce parasitic capacitance by vertically stacking the memory cells,

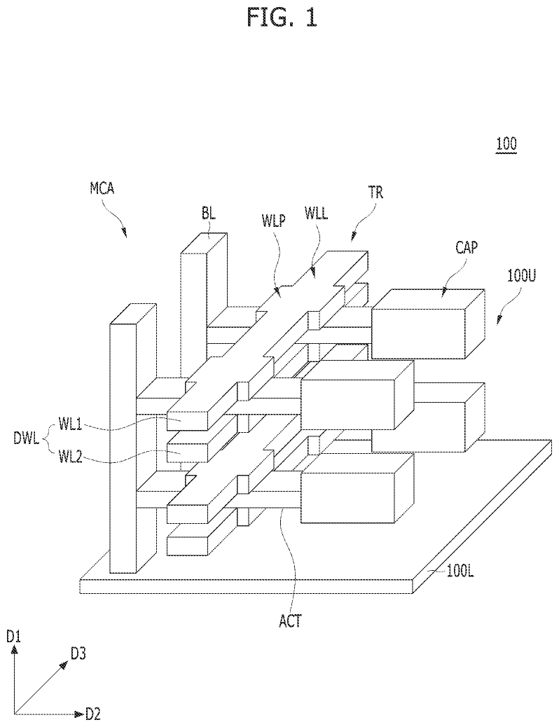

FIG. 1 is a schematic perspective view illustrating a semiconductor device in accordance with an embodiment of the present invention.

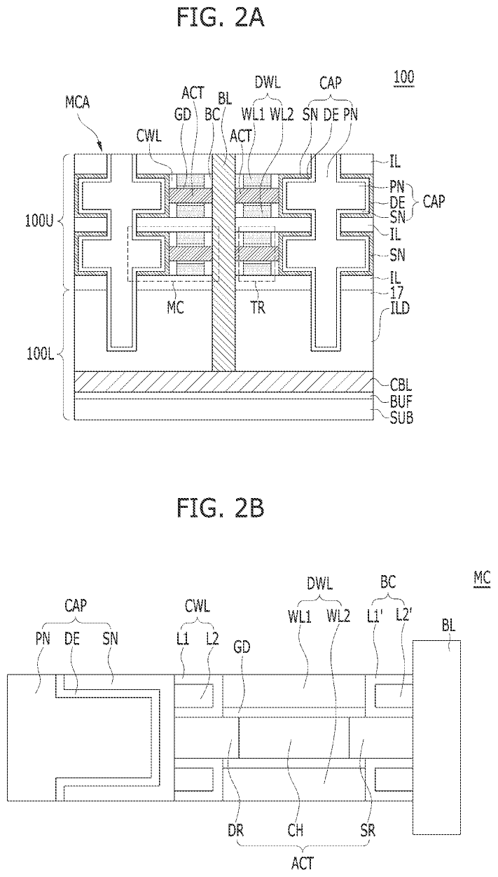

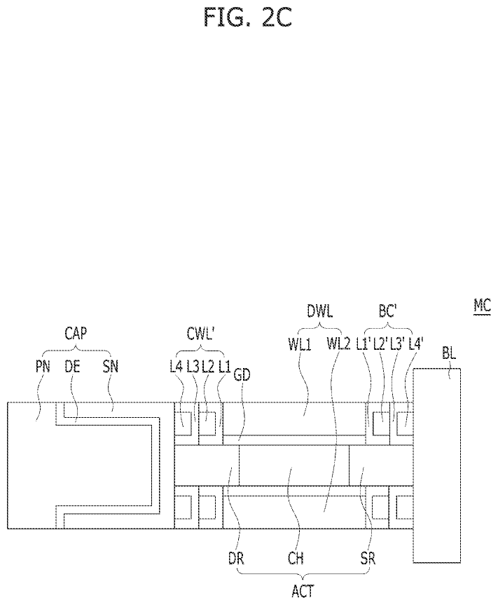

FIG. 2A is a schematic cross-sectional view illustrating a semiconductor device in accordance with an embodiment of the present invention. FIG. 2A illustrates mirror-type memory cells array sharing a bit line, FIG. 2B illustrates an enlarged view of a memory cell MC in more detail.

Referring to FIGS. 1 to 2B, the semiconductor device 100 in accordance with an embodiment of the present invention may include a lower structure 100L and an upper structure 100U formed over the lower structure 100L.

The lower structure 100L may include a substrate SUB, a buffer layer BUF, a bit line pad CBL, and an inter-layer dielectric structure ILD.

The upper structure 100U may include a memory cell array MCA including a plurality of memory cells MC. Cell isolation layers IL may be disposed between the memory cells MC that are stacked in a first direction D1. The cell isolation layers IL may include silicon oxide.

Each of the memory cells MC may include a transistor TR and a data storage element CAP. The transistor TR may include an active layer ACT and a word line DWL.

The word line DWL may include a double word line. For example, the transistor TR of each memory cell MC may include one double word line, and the double word line may include a first word line WL1 and a second word line WL2 facing each other with the active layer ACT interposed therebetween.

The data storage element CAP may be memory elements capable of storing data. The data storage element CAP may include a capacitor, a magnetic tunnel junction, or a phase change material. According to an embodiment of the present invention, the data storage element CAP may be a capacitor. Hereinafter, the data storage dement CAP may be simply referred to as a capacitor CAP.

The capacitor CAP may include a first electrode SN, a dielectric layer DE, and a second electrode PN. The upper structure 100U may include a bit line BL, active layers ACT, word lines DWL, and capacitors CAP. One side of the transistors TR may be coupled to the bit line BL, and another side of the transistors TR may be coupled to the capacitors CAP, respectively. In other words, the ends of one side of the active layers ACT may be commonly coupled to the bit line BL, and the ends of another side of the active layers ACT may be respectively coupled to the first electrodes SN of the capacitors CAP.

The bit line BL may extend in a first direction D1 perpendicular to the surface of the substrate SUB. The active layers ACT may extend in a second direction D2 which is parallel to the surface of the substrate SUB. The word lines DWL may extend in a third direction D3 which is also parallel to the surface of the substrate SUB. Here, the first direction D1, the second direction D2, and the third direction D3 may cross each other. The bit line BL may be a vertical conductive line which is oriented vertically in the first direction D1, and the word line DWL may be a horizontal conductive line which is oriented horizontally in the third direction D3. The active layer ACT may be a horizontal conductive layer which is oriented horizontally in the second direction D2. The first, second, and third directions D1, D2, and D3 in the illustrated embodiment are orthogonal to each other.

The bit line BL may be vertically oriented in the first direction D1. The bit line BL may be electrically connected to a bit line pad CBL of the lower structure 100L, The bit line BL may be referred to as a vertically oriented bit line or a pillar-type bit line. The bit line BL may include a conductive material. The bit line BL may include a silicon-based material, a metal-based material, or a combination thereof. The bit line BL may include silicon, a metal, a metal nitride, a metal silicide, or a combination thereof. The bit line BL may include polysilicon, titanium nitride, tungsten, or a combination thereof. For example, the bit line BL may include polysilicon or titanium nitride (TiN) which is doped with an N-type impurity. The bit line BL may include a TiN/W stack including titanium nitride and tungsten over titanium nitride.

The bit line pad CBL may include a conductive material. For example, the bit line pad CBL may include a metal-based material. The bit line pad CBL may include tungsten, titanium nitride, or a combination thereof. The bit line BL and the bit line pad CBL may be electrically connected.

The active layer ACT may be horizontally arranged in the second direction D2 from the bit line BL. The double word line DWL may include a pair of word lines, that is, a first word line WL1 and a second word line WL2. The first word line WL1 and the second word line WL2 may face each other with the active layer ACT interposed therebetween. A gate dielectric layer GD may be formed on the upper and lower surfaces of the active layer ACT.

The active layer ACT may include a semiconductor material or an oxide semiconductor material. For example, the active layer ACT may include monocrystalline silicon, germanium, silicon germanium, or indium gallium zinc oxide (IGZO). The active layer ACT may include polysilicon or monocrystalline silicon.

The active layer ACT may include a channel CH, a first source/drain region SR between the channel CH and the bit line BL, and a second source/drain region DR between the channel CH and the capacitor CAP. The channel CH may be defined between the first source/drain region SR and the second source/drain region DR. The first source/drain region SR and the second source/drain region DR may be doped with impurities of the same conductivity type. The first source/drain region SR and the second source/drain region DR may be doped with an N-type impurity or a P-type impurity. The first source/drain region SR and the second source/drain region DR may include at least one impurity selected among arsenic (As), phosphorus (P), boron (B), indium (In), and a combination thereof. The first source/drain region SR may contact the bit line BL, and the second source/drain region DR may contact the first electrode SN.

The transistor TR may be a cell transistor and it may have a word line DWL. In the word line DWL, the first word line WL1 and the second word line WL2 may have the same potential. For example, the first word line WL1 and the second word line WL2 may form a pair, and the same word line driving voltage may be applied to the first word line WL1 and the second word line WL2. As described, the memory cell MC according to the illustrated embodiment of the present invention may have a double word line DWL in which two first and second word lines WL1 and WL2 are disposed adjacent to one channel CH.

Each word line WL1 and WL2 of the double word line DWL may include a line-shaped portion WLL and a plurality of protrusion portions WLP which are spaced apart at regular intervals and are positioned to overlap with corresponding active layers ACT. A notch-type sidewall may be provided by the line-shaped portion WLL and the protrusion portions WLP. The word line DWL may include two notch-type sidewalls facing each other. In the illustrated embodiment of FIG. 1, each sidewall of each word line WL1 and WL2 of the double word line DWL has a plurality of rectangular shape protrusions alternating with rectangular shape notches with the positioning of the protrusions overlapping with the active layers ACT.

According to another embodiment of the present invention, the word line DWL may have a structure formed of only the line-shaped portion WLL without the protrusion portions WLP, The line-shaped portion WLL may provide a non-notch-type sidewall, that is, flat sidewalls extending in the third direction D3.

According to another embodiment of the present invention, the first word line WL1 and the second word line WL2 may have different potentials. For example, a word line driving voltage may be applied to the first word line WL1, and a ground voltage may be applied to the second word line WL2, The second word line WL2 may be referred to as a back word line or a shield word line. According to another embodiment of the present invention, the ground voltage may be applied to the first word line WL1, and the word line driving voltage may be applied to the second word line WL2.

According to another embodiment of the present invention, the word line DWL may have a single word line structure, that is, the word line DWL may include only the first word line WL1 or only the second word line WL2.

According to another embodiment of the present invention, the word line DWL may have a gate-all-around structure. The gate-all-around structure may extend in the third direction D3 while surrounding the active layers ACT.

The gate dielectric layer GD may include silicon oxide, silicon nitride, a metal oxide, a metal oxynitride, a metal silicate, a high-k material, a ferroelectric material, an anti-ferroelectric material or a combination thereof. The gate dielectric layer GD may include SiO₂, Si₃N₄, HfO₂, Al₂O₃, ZrO₂, AlON, HfON, HfSiO, HfSiON, or HfZrO.

The first and second word lines WL1 and WL2 of the word line DWL may include a metal, a metal mixture, a metal alloy, or a semiconductor material. The word line DWL may include titanium nitride, tungsten, polysilicon, or a combination thereof. For example, each of the first and second word lines WL1 and WL2 of the word line DWL may include a TiN/W stack in which titanium nitride and tungsten are sequentially stacked. The first and second word lines WL1 and WL2 of the word line DWL may include an N-type work function material or a P-type work function material. The N-type work function material may have a low work function of approximately 4.5 eV or less, and the P-type work function material may have a high work function of approximately 4.5 eV or more.

The capacitor CAP may be disposed horizontally from the transistor TR. The capacitor CAP may include a first electrode SN that extends horizontally from the active layer ACT. The capacitor CAP may further include a dielectric layer DE and a second electrode PN over the first electrode SN. The first electrode SN, the dielectric layer DE, and the second electrode PN may be arranged horizontally. The first electrode SN may have a horizontally oriented cylinder shape. The dielectric layer DE may conformally cover the cylindrical inner wall and the cylindrical outer wall of the first electrode SN. The second electrode PN may have a shape extending to the cylindrical inner wall and the cylindrical outer wall of the first electrode SN over the dielectric layer DE.

The first electrode SN may have a three-dimensional structure, and the first electrode SN of the three-dimensional structure may have a horizontal three-dimensional structure which is oriented in the second direction D2. As an example of the three-dimensional structure, the first electrode SN may have a cylinder shape.

According to another embodiment of the present invention, the first electrode SN may have a pillar shape or a pylinder shape. The pylinder shape may refer to a structure in which a pillar shape and a cylinder shape are merged.

The second electrode PN may be shared by the capacitors CAP. The second electrode PN may extend into the inter-layer dielectric layer ILD of the lower structure 100L. The second electrode PN may not be coupled to the bit line pad CBL. The second electrodes PN shared by the capacitors CAP may be referred to as plate lines.

The first electrode SN and the second electrode PN may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack. The second electrode PN may include a combination of a metal-based material and a silicon-based material. For example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the cylindrical inside of the first electrode SN over the titanium nitride, and titanium nitride (TiN) may serve as a second electrode PN of a capacitor CAP, and tungsten nitride may be a low-resistance material.

The dielectric layer DE may be referred to as a capacitor dielectric layer. The dielectric layer DE may include silicon oxide, silicon nitride, a high-k material, or a combination thereof. The high-k material may have a higher dielectric constant than silicon oxide. Silicon oxide (SiO₂) may have a dielectric constant of approximately 3.9, and the dielectric layer DE may include a high-k material having a dielectric constant of approximately 4 or more. The high-k material may have a dielectric constant of approximately 20 or more. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃), According to another embodiment of the present invention, the dielectric layer DE may be formed of a composite layer including two or more layers of the aforementioned high-k materials.

The dielectric layer DE may be formed of zirconium (Zr)-based oxide. The dielectric layer DE may have a stack structure including at least zirconium oxide (ZrO₂). The stack structure including zirconium oxide (ZrO₂) may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide (ZrO₂)-based layer. According to another embodiment of the present invention, the dielectric layer DE may be formed of hafnium (Hf)-based oxide. The dielectric layer DE may have a stack structure including at least hafnium oxide (HfO₂). The stack structure including hafnium oxide (HfO₂) may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as a hafnium oxide (HfO₂)-based layer. In the ZA stack, ZAZ stack, HA stack, and HAH stack, aluminum oxide (Al₂O₃) may have a greater bandgap energy (which will be, hereinafter, simply referred to as bandgap) than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap than the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material.

According to another embodiment of the present invention, the dielectric layer DE may include a laminated structure in which a high-k material and a high-bandgap material are alternately stacked. For example, it may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the dielectric layer DE may include a stack structure, a laminated structure, or a mixed structure including zirconium oxide, hafnium oxide, and aluminum oxide.

According to another embodiment of the present invention, the dielectric layer DE may include a ferroelectric material or an antiferroelectric material.

According to another embodiment of the present invention, an interface control layer for improving leakage current may be further formed between the first electrode SN and the dielectric layer DE. The interface control layer may include titanium oxide (TiO₂), niobium oxide, or niobium nitride. The interface control layer may also be formed between the second electrode PN and the dielectric layer DE.

The capacitor CAP may include a metal-insulator-metal (MIM) capacitor. The first electrode SN and the second electrode PN may include a metal-based material.

The capacitor CAP may be replaced with another data storage material. For example, the data storage material may be a phase change material, a magnetic tunnel junction (MTJ), or a variable resistance material.

A first capping layer CWL may be disposed between the word lines DWL and the first electrode SN. The interface between the first capping layer CWL and the active layer ACT may include a trap-suppressing interface. For example, the trap-suppressing interface may refer to an interface with relatively few traps or no traps. The trap-suppressing interface may include a non-trap interface or a trap-free interface. Here, the trap-suppressing interface may refer to a non-nitride interface. The non-nitride interface may include a silicon-oxygen interface (Si—O interface) and may not include a silicon-nitrogen interface (Si—N interface). The first capping layer CWL may include a trap-suppressing material. For example, the trap-suppressing material may include an oxide-based material in direct contact with the active layer ACT. The first capping layer CWL may include a first liner L1 and a second liner L2. The first liner L1 may be a trap-suppressing material, and the second liner L2 may be a nitride-based material. The first liner L1 may be referred to as a trap-suppressing capping layer, and the second liner L2 may be referred to as a nitrogen-containing capping layer. The first liner L1 may be a nitrogen-free material, and the second liner L2 may be a nitrogen-containing material. The first liner L1 may be of silicon oxide, and the second liner L2 may be of silicon nitride. The first liner L1 may be nitrogen-free silicon oxide. The nitrogen-free silicon oxide may include SiO₂. The nitrogen-free silicon oxide may not contain Si₃N₄ or SiON. The first liner L1 may be referred to as a blocking layer. As will be described later, the first liner L1 and the second liner L2 may serve as etch stoppers. The first liner L1 may directly contact the active layer ACT, The second liner L2 may not directly contact the active layer ACT due to the first liner L1. When the second liner L2 includes silicon nitride, since the silicon nitride does not directly contact the active layer ACT, defects originating from the traps may be suppressed. As a comparative example, when the first liner L1 is silicon nitride or the second liner L2 is in direct contact with the active layer, a trap may be caused so as to deteriorate off-leakage, According to another embodiment of the present invention, the first liner L1 may include silicon carbon oxide (SiCO).

As described above, since the first liner L1 is formed of nitrogen-free silicon oxide having relatively few traps, gate induced drain leakage (GIDL) may be improved.

A second capping layer BC may be disposed between the word lines DWL and the bit line BL, The second capping layer BC may be referred to as a bit line-side capping layer. The second capping layer BC may include a trap-suppressing capping layer. The second capping layer BC may have the same structure as that of the first capping layer CWL, that is, the second capping layer BC may have a first liner L1′ and a second liner L2′. The first liner L1′ may be a trap-suppressing material, and the second liner L2′ may be a nitride-based material. The first liner L1′ may be referred to as a trap-suppressing capping layer, and the second liner L2″ may be referred to as a nitrogen-containing capping layer. The first liner may be a nitrogen-free material, and the second liner L2′ may be a nitrogen-containing material. The first liner L1′ may be nitrogen-free silicon oxide, and the second liner L2′ may be silicon nitride. The first liner L1′ may be referred to as a blocking layer. The first liner L1′ may directly contact the active layer ACT. The second liner L2′ may not directly contact the active layer ACT by the first liner L1′. When the second liner L2′ includes silicon nitride, the silicon nitride does not directly contact the active layer ACT. Therefore, the defects caused by the traps may be suppressed.

As a comparative example, when the first liner L1′ is silicon nitride or the second liner L2′ directly contacts the active layer ACT, a trap may be induced so as to deteriorate the off-leakage.

A gate dielectric layer GD may be disposed between the second capping layer BC and the active layer ACT. According to another embodiment of the present invention, the second capping layer BC and the active layer ACT may be in direct contact, and in this case, the interface between the second capping layer BC and the active layer ACT may include a trap-suppressing interface, which is a non-nitride interface. The non-nitride interface may include a silicon-oxygen interface (Si—O interface) and may not include a silicon-nitrogen interface (Si—N interface).

The memory cell array MCA may include a plurality of memory cells MC, and each of the memory cells MC may include a vertically oriented bit line BL, a horizontally oriented active layer ACT, a word line DWL, and a horizontally oriented capacitor CAP. For example, FIG. 1 illustrates a three-dimensional Dynamic Random Access Memory (DRAM) memory cell array including four memory cells MC.

The active layers ACT disposed adjacent to each other in the first direction D1 may contact one bit line BL. The active layers ACT disposed adjacent to each other in the third direction D3 may share one word line DWL. The capacitors CAP may be respectively coupled to the active layers ACT in a one to one correspondence.

In the memory cell array MCA, a plurality of word lines DWL may be vertically stacked in the first direction D1. Each word line DWL may include a pair of a first word line WL1 and a second word line WL2. Between the first word line WL1 and the second word line WL2, a plurality of active layers ACT may be horizontally arranged to be spaced apart from each other in the third direction D2.

The lower structure 100L may further include a peripheral circuit portion. The peripheral circuit portion may be disposed between the substrate SUB and the buffer layer BUF. The peripheral circuit portion may be disposed at a lower level than the memory cell array MCA, This may be referred to as a COP (Cell over PERI) structure. The peripheral circuit portion may include at least one control circuit for driving the memory cell array MCA, The at least one control circuit of the peripheral circuit portion may include an IN-channel transistor, a P-channel transistor, a CMOS circuit, or a combination thereof. The at least one control circuit of the peripheral circuit portion PERI may include an address decoder circuit, a read circuit, a write circuit, and the like. The at least one control circuit of the peripheral circuit portion may include a planar channel transistor, a recess channel transistor, a buried gate transistor, a fin channel transistor (FinFET), etc.

For example, the peripheral circuit portion may include sub-word line drivers and a sense amplifier. The word lines DWL may be coupled to sub-word line drivers, and the bit lines BL may be coupled to the sense amplifier. The interconnection structure, such as a multi-level metal, may be disposed between the peripheral circuit portion and the memory cell array MCA.

According to another embodiment of the present invention, the peripheral circuit portion may be disposed at a higher level than the memory cell array MCA, This may be referred to as a POC (PERI over Cell) structure.

FIG. 2C is a schematic cross-sectional view illustrating a memory cell in accordance with another embodiment of the present invention. The memory cell MC of FIG. 2C may be similar to the memory cell of FIG. 2B. Hereinafter, for the constituent elements also appearing in FIGS. 1 to 2B, reference may be made to the descriptions of FIGS. 1 to 2B.

Referring to FIG. 2C, the memory cell MC may include a bit line BL, a word line DWL, an active layer ACT, and a capacitor CAP. The word line DWL may be a double word line, and it may include a first word line WL1 and a second word line WL2 facing each other with the active layer ACT interposed therebetween. The capacitor CAP may include a first electrode SN, a dielectric layer DE, and a second electrode PN. The active layer ACT may include a first source/drain region SR, a second source/drain region DR, and a channel CH.

A first capping layer CWL′ may be disposed between the word lines DWL and the first electrode SN, A second capping layer BC′ may be disposed between the word lines DWL and the bit line BL. The second capping layer BC′ may be referred to as a bit line-side capping layer.

The interface between the first capping layer CWL′ and the active layer ACT and the interface between the second capping layer BC′ and the active layer ACT may include a trap-suppressing interface. For example, the trap-suppressing interface may refer to an interface having relatively few traps or no traps. The trap-suppressing interface may include a non-trap interface or a trap-free interface. Here, the trap-suppressing interface may refer to a non-nitride interface. The non-nitride interface may include a silicon-oxygen interface (Si—O interface) and may not include a silicon-nitrogen interface (Si—N interface). The first capping layer CWL′ and the second capping layer BC′ may include a trap-suppressing material. For example, the trap-suppressing material may include an oxide-based material in direct contact with the active layer ACT.

The first capping layer CWL′ may include a first liner L1, a second liner L2, a third liner L3, and a fourth liner L4. The second capping layer BC′ may have the same structure as that of the first capping layer CWL′, that is, the second capping layer BC′ may include the first liner L1′, the second liner L2′, the third liner L3′, and the fourth liner L4′.

The first liner L1 and L1′ and the third liner L3 and L3′ may be a trap-suppressing material, and the second liner L2 and L2′ and the fourth liner L4 and L4′ may be a nitride-based material. The first liner L1 and L1′ and the third liner L3 and L3′ may be referred to as a trap-suppressing capping layer, and the second liner L2 and L2′ and the fourth liner L4 and L4′ may be referred to as a nitrogen-containing capping layer. The first liner L1 and L1′ and the third liner L3 and L3′ may be a nitrogen-free material, and the second liner L2 and L2′ and the fourth liner L4 and L4′ may be a nitrogen-containing material. The first liners L1 and L1′ and the third liners L3 and L3′ may be silicon oxide, and the second liners L2 and L2′ and the fourth liners L4 and L4′ may be silicon nitride. A combination of the first liner L1 and L1′, the second liner L2 and L2′, the third liner L3 and L3′, and the fourth liner L4 and L4′ may be an ONON (Oxide-Nitride-Oxide-Nitride) structure. The first liners L1 and L1′ and the third liners L3 and L3′ may be nitrogen-free silicon oxide. The nitrogen-free silicon oxide may include SiO₂. The nitrogen-free silicon oxide may not contain Si₃N₄ or SiON. The first liners L1 and L1′ and the third liners L3 and L3′ may directly contact the active layer ACT. The second liner L2 and L2′ and the fourth liner L4 and L4′ may not directly contact the active layer ACT because of the first liner L1 and L1′ and the third liner L3 and L3′. When the second liners L2 and L2′ and the fourth liners L4 and L4′ include silicon nitride, the silicon nitride does not directly contact the active layer ACT. Therefore, defects that may be caused by traps may be suppressed. According to another embodiment of the present invention, the first liners L1 and L1′ and the third liners L3 and L3′ may include silicon carbon oxide (SiCO).

As described above, since the first liners L1 and L1′ and the third liners L3 and L3′ are formed of nitrogen-free silicon oxide having relatively few traps, at is possible to improve Gate Induced Drain Leakage (GIDL).

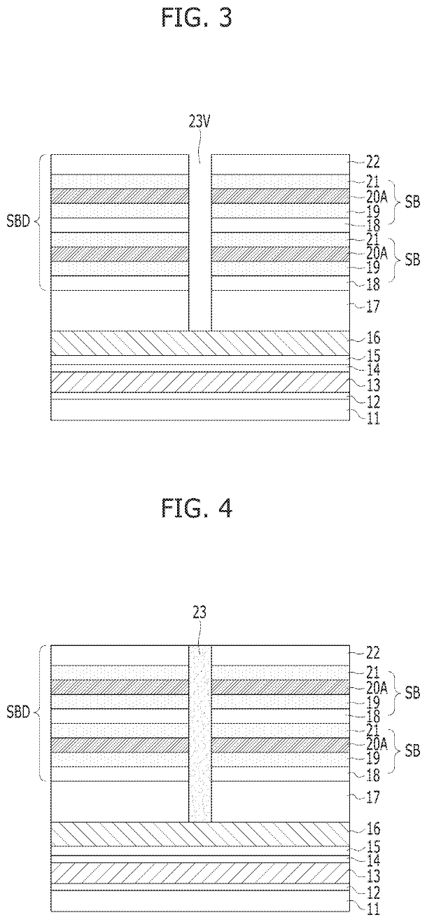

FIGS. 3 to 16 are cross-sectional views illustrating a method for fabricating a semiconductor device in accordance with an embodiment of the present invention.

Referring to FIG. 3, a buffer layer 12 may be formed over the substrate 11. The buffer layer 12 may include a dielectric material. The buffer layer 12 may include silicon oxide.

A bit line pad 13 may be formed over the buffer layer 12. The bit line pad 13 may include a conductive material. For example, the hit line pad 13 may include a metal-based material. The hit line pad 13 may include tungsten, titanium nitride, or a combination thereof.

An etch stop layer 14 may be formed over the bit line pad 13. The etch stop layer 14 may include a dielectric material. The etch stop layer 14 may include silicon nitride. The etch stop layer 14 may be referred to as a ‘dielectric etch stop layer’.

A first inter-layer dielectric layer 15 may be formed over the etch stop layer 14, The first inter-layer dielectric layer 15 may include silicon oxide.

A sacrificial pad 16 may be formed over the first inter-layer dielectric layer 15. The sacrificial pad 16 may include a metal-based material. The sacrificial pad 16 may include tungsten, titanium nitride, or a combination thereof.

The sacrificial pad 16 may serve as an etch stop layer during a subsequent etch process. The sacrificial pad 16 may be referred to as a ‘metallic etch stop layer’.

A second inter-layer dielectric layer 17 may be formed over the sacrificial pad 16. The second inter-layer dielectric layer 17 may include silicon oxide.

A stack body SBD may be formed over the second inter-layer dielectric layer 17. The stack body SBD may include a sub-stack SB in which a cell isolation layer 18, a first sacrificial layer 19, a semiconductor layer 20A, and a second sacrificial layer 21 are stacked in the mentioned order. The stack body SBD may be formed by repeatedly stacking a plurality of sub-stacks SB. An uppermost cell isolation layer 22 may be formed on top of the stack body SBD. The uppermost cell isolation layer 22 may be thicker than the other cell isolation layers 18. The stack body SBD may include a plurality of cell isolation layers 18, a plurality of first sacrificial layers 19, a plurality of semiconductor layers 20A, and a plurality of second sacrificial layers 21. The stack body SBD may have a structure in which a triple layer of the first sacrificial layer 19/the semiconductor layer 20A/the second sacrificial layer 21 is disposed between the cell isolation layers 18.

The cell isolation layers 18 and the uppermost cell isolation layer 22 may include silicon oxide. The first and second sacrificial layers 19 and 21 may include silicon nitride. The semiconductor layers 20A may include a semiconductor material or an oxide semiconductor material. For example, the semiconductor layers 20A may include silicon, monocrystalline silicon, polysilicon, silicon germanium, an oxide semiconductor material, or a combination thereof.

Subsequently, a first opening 23V passing through a first portion of the stack body SBD may be formed. The first opening 23V may extend to pass through the second inter-layer dielectric layer 17 and expose the sacrificial pad 16. In other words, the first opening 23V may penetrate the stack body SBD and the second inter-layer dielectric layer 17. The stack body SBD and the second inter-layer dielectric layer 17 may be sequentially etched to form the first opening 23V. An etching process for forming the first opening 23V may stop at the sacrificial pad 16.

Referring to FIG. 4, a sacrificial vertical structure 23 filling the first opening 23V may be formed. The step of forming the sacrificial vertical structure 23 may include depositing a dielectric material to fill the first opening 23V followed by a planarization process for removing any excess dielectric material over the opening 23V. The first sacrificial vertical structure 23 may include silicon oxide, silicon nitride, silicon carbon oxide, or a combination thereof.

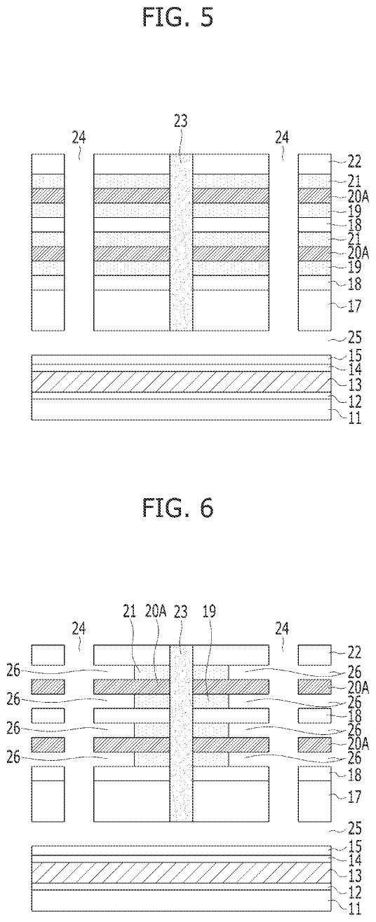

Referring to FIG. 5, second openings 24 passing through a second portion of the stack body SBD may be formed. The second openings 24 may extend to pass through the second inter-layer dielectric layer 17 to expose the sacrificial pad 16, In other words, the second openings 24 may penetrate the stack body SBD and the second inter-layer dielectric layer 17. The stack body SBD and the second inter-layer dielectric layer 17 may be sequentially etched to form the second openings 24. An etching process for forming the second openings 24 may stop at the sacrificial pad 16.

A pair of second openings 24 may be formed by being spaced apart from each other with the sacrificial vertical structure 23 interposed therebetween.

Subsequently, the sacrificial pad 16 below the second openings 24 may be removed. The sacrificial pad 16 may be removed using dry etching or wet etching. The space from which the sacrificial pad 16 is removed forms a horizontal level recess 25. The horizontal level recess 25 may be disposed between the second inter-layer dielectric layer 17 and the first inter-layer dielectric layer 15.

Referring to FIG. 6, the first and second sacrificial layers 19 and 21 may be partially removed through the second openings 24. As a result, a pair of sacrificial layer-level recesses 26 may be formed with the semiconductor layer 20A interposed therebetween, Portions of the semiconductor layers 20A may be exposed by the sacrificial layer-level recesses 26.

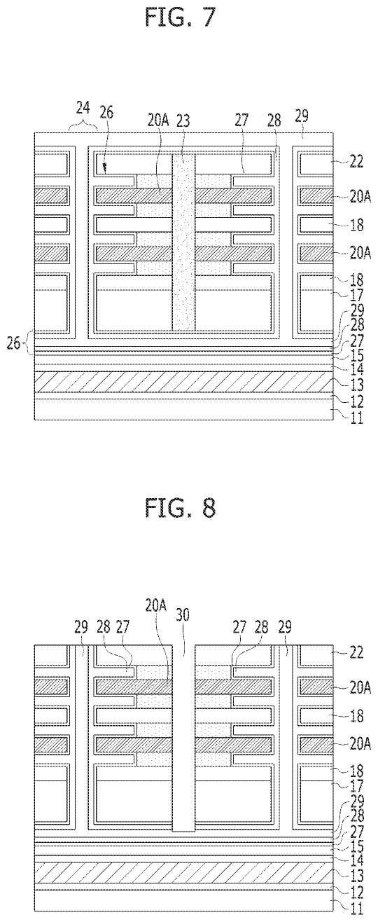

Referring to FIG. 7, a first liner layer 27 and a second liner layer 28 may be sequentially formed over the sacrificial layer-level recesses 26, The first liner layer 27 may conformally cover the surfaces of the sacrificial layer-level recesses 26. The second liner layer 28 may fill the sacrificial layer-level recesses 26 over the first liner layer 27.

A gap-fill layer 29 may be formed over the second liner layer 28. The gap-fill layer 29 may fill the second openings 24 over the second liner layer 28. The first liner layer 27, the second liner layer 28, and the gap-fill layer 29 may fill the horizontal level recess 25.

The first liner layer 27 may be silicon oxide, in particular nitrogen-free silicon oxide. The second liner layer 28 may be silicon nitride.

Referring to FIG. 8, the gap-fill layer 29, the second liner layer 28, and the first liner layer 27 may be planarized to expose the surface of the uppermost cell isolation layer 22.

Subsequently, the sacrificial vertical structure 23 may be removed to form a bit line opening 30. The sacrificial vertical structure 23 may be removed by a dry etching process or a wet etching process, After removing the sacrificial vertical structure 23, a portion of the first liner layer 27 and the second liner layer 28 disposed in the horizontal level recess 25 may be removed to expand the bit line opening 30.

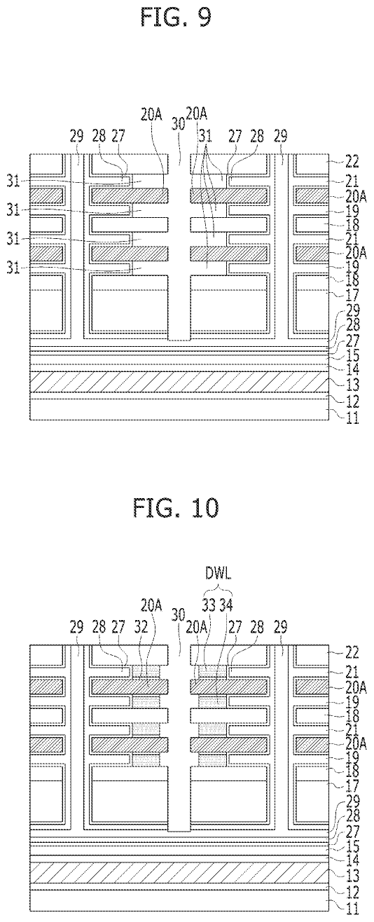

Referring to FIG. 9, the remaining first and second sacrificial layers 19 and 21 may be removed to form the word line-level recesses 31, As the remaining of the first and second sacrificial layers 19 and 21 are removed, a pair of word line-level recesses 31 may be formed with the semiconductor layer 20A interposed therebetween. The first liner layer 27 may serve as an etch stopper while the word line-level recesses 31 are formed. For example, when the first liner layer 27 includes silicon oxide and the first and second sacrificial layers 19 and 21 include silicon nitride, the first liner layer 27 may serve as an etch stopper while removing the first and second sacrificial layers 19 and 21. The first and second sacrificial layers 19 and 21 may be removed by a dry etching process or a wet etching process.

Referring to FIG. 10, a gate dielectric layer 32 may be formed over the exposed portions of the semiconductor layers 20A. The gate dielectric layer 32 may be selectively formed on the surfaces of the semiconductor layer 20A by an oxidation process. According to another embodiment of the present invention, the gate dielectric layer 32 may be formed by a deposition process. In this case, a gate dielectric layer 32 may be formed on the surface of the word line-level recesses 31 and on the surface of the semiconductor layers 20A.

Subsequently, a word line DWL may be formed by filling the word line-level recesses 31 with a conductive material. The word line DWL may include polysilicon, titanium nitride, tungsten, or a combination thereof. For example, the step of forming the word line DWL may include conformally depositing titanium nitride, depositing tungsten over the titanium nitride to fill the word line-level recesses 31, and performing an etch-back process on the titanium nitride and tungsten. The word line DWL may partially fill the word line-level recesses 31, and as a result, a portion of the gate dielectric layer 32 may be exposed. Each word line DWL may include a pair of a first word line 33 and a second word line 34, The first word line 33 and the second word line 34 may vertically face each other with the semiconductor layer 20A interposed therebetween. The ends of one side of the semiconductor layers 20A may be exposed while the word line DWL is formed or after the word line DWL is formed.

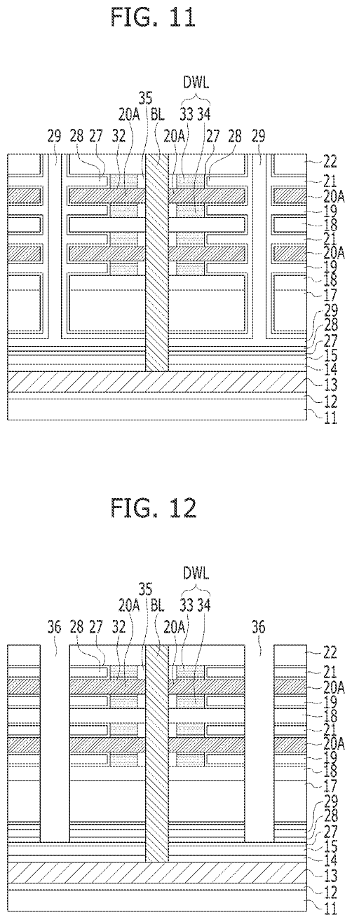

Referring to FIG. 11, bit line-side capping layers 35 contacting the ends of one side of the word lines DWL may be formed. The bit line-side capping layers 35 may be disposed in the word line-level recesses 31. The bit line-side capping layers 35 may include a trap-suppressing capping layer. The bit line-side capping layers 35 may include a nitrogen-free silicon oxide as the trap-suppressing capping layer.

According to another embodiment of the present invention, the bit line-side capping layer 35 may correspond to the bit line-side capping layer BC as described with reference to FIG. 2B. The bit line-side capping layers 35 may include a silicon oxide liner and a silicon nitride liner over the silicon oxide liner. Here, the silicon oxide liner may correspond to the first liner L1′ shown in FIG. 2B, and the silicon nitride liner may correspond to the second liner L2′ of FIG. 2B.

Subsequently, a bit line BL may be formed. The bit line BL may have a pillar shape filling the bit line opening 30. The bit line BL may include titanium nitride, tungsten, or a combination thereof.

Referring to FIG. 12, vertical openings 36 may be formed. The vertical openings 36 may be formed by etching the first liner layer 27, the second liner layer 28, the gap-fill layer 29, and the second inter-layer dielectric layer 17. The ends of another side of the semiconductor layers 20A may be exposed by the vertical openings 36. A stack of the first liner layer 27 and the second liner layer 28 may remain between the cell isolation layers 18 and the semiconductor layers 20A. The stack of the first liner layer 27 and the second liner layer 28 may also remain between the uppermost cell isolation layer 22 and the uppermost semiconductor layer 20A.

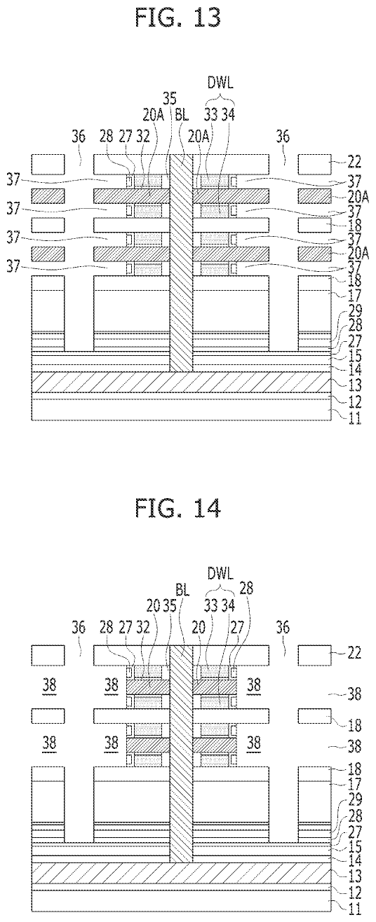

Referring to FIG. 13, the first liner layer 27 and the second liner layer 28 may be horizontally recessed through the vertical openings 36. As a result, capping layer-level recesses 37 exposing the surfaces of the semiconductor layers 20A may be formed, and the stack of the first liner 27 and the second liner 28 may remain on one sidewall of the word lines DWL. The first liner 27 and the second liner 28 may be referred to as a ‘capacitor-side-capping layer’. The first liner 27 may be a trap-suppressing capping layer, and the second liner 28 may be a nitrogen-free capping layer. A combination of the first liner 27 and the second liner 28 may correspond to the capacitor side-capping layer CWL as described above with reference to FIG. 2B. In other words, the first liner 27 may correspond to the first liner L1 shown in FIG. 2B, and the second liner 28 may correspond to the second liner L2 shown in FIG. 2B.

Referring to FIG. 14, the semiconductor layers 20A may be selectively etched to form the active layers 20. As a result, capacitor openings 38 may be formed between the cell isolation layers 18 and 22.

The second liner 28 may serve as an etch stopper while the capacitor openings 38 are formed.

As described above, the bit line-side capping layer 35 may include silicon oxide, and the bit line-side capping layer 35 may directly contact the active layer 20.

The first liner 27 may directly contact the active layer 20, and the second liner 28 may not contact the active layer 20. When the second liner 28 includes silicon nitride, direct contact between the second liner 28 and the active layer 20 may be blocked by the first liner 27, thus suppressing a defect that may be caused by a trap from occurring.

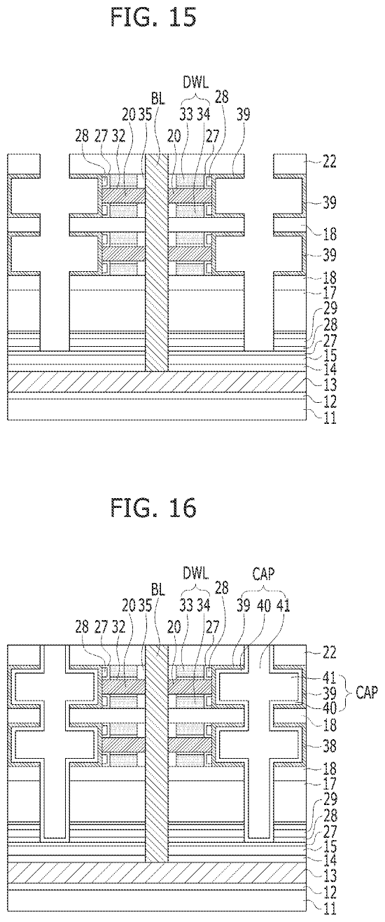

Referring to FIG. 15, the first electrode 39 coupled to the active layer 20 may be formed. The first electrode 39 may be formed by depositing a conductive material and performing an etch-back process. The first electrode 39 may include titanium nitride. The first electrode 39 may have a horizontally oriented cylindrical shape. The first electrode 39 may be formed in the inside of the capacitor opening 38.

Referring to FIG. 16, the dielectric layer 40 and the second electrode 41 may be sequentially formed over the first electrode 39. As a result, a capacitor CAP may be formed, and the capacitor CAP may include the first electrode 39, the dielectric layer 40, and the second electrode 41.

According to the embodiment of the present invention, since the capping layer in contact with the active layer includes a trap-suppressing material, it is possible to improve Gate Induced Drain Leakage (GIRL).

The effects desired to be obtained in the embodiments of the present invention are not limited to the effects mentioned above, and other effects not mentioned above may also be clearly understood by those of ordinary skill in the art to which the present invention pertains from the description below.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a lower structure;
an active layer over the lower structure;
a bit line coupled to one side of the active layer and extending vertically from the lower structure;
a data storage element coupled to another side of the active layer;
a word line disposed adjacent to the active layer and extending in a direction crossing the active layer; and
a capping layer disposed between the word line and the data storage element and including a trap-suppressing material in contact with the active layer.

2. The semiconductor device of claim 1, wherein the trap-suppressing material of the capping layer is in direct contact with the active layer and the word line.

3. The semiconductor device of claim 1, wherein the trap-suppressing material of the capping layer includes a nitrogen-free material.

4. The semiconductor device of claim 1, wherein the trap-suppressing material of the capping layer includes an oxide-based material in direct contact with the active layer.

5. The semiconductor device of claim 1,
wherein the capping layer further includes a nitride-based material over the trap-suppressing material, and
wherein the trap-suppressing material is disposed between the nitride-based material and the active layer.

6. The semiconductor device of claim 5,
wherein the trap-suppressing material includes silicon oxide, and
wherein the nitride-based material includes silicon nitride.

7. The semiconductor device of claim 1, further comprising:
a gate dielectric layer on a surface of the active layer.

8. The semiconductor device of claim 1, wherein the active layer includes a monocrystalline silicon, polysilicon or an oxide semiconductor material.

9. The semiconductor device of claim 1, wherein the word line includes double word lines facing each other with the active layer interposed therebetween.

10. The semiconductor device of claim 1, wherein the lower structure includes:
a substrate; and
a bit line pad disposed over the substrate and coupled to the bit line.

11. The semiconductor device of claim 1, wherein the lower structure includes a peripheral circuit portion.

12. The semiconductor device of claim 1,
wherein the active layer includes monocrystalline silicon, and
wherein the trap-suppressing material of the capping layer includes nitrogen-free silicon oxide.

13. The semiconductor device of claim 1, further comprising:
a bit line-side capping layer disposed between the bit line and the word.

14. The semiconductor device of claim 13, wherein the bit line-side capping layer includes a trap-suppressing capping layer in contact with the active layer and the word line.

15. The semiconductor device of claim 14,
wherein the bit line-side capping layer further includes a nitrogen-containing capping layer over the trap-suppressing capping layer, and
wherein the trap-suppressing capping layer is disposed between the nitrogen-containing capping layer and the active layer.

16. The semiconductor device of claim 15, wherein the trap-suppressing capping layer includes silicon oxide.

17. The semiconductor device of claim 15, wherein the nitrogen-containing capping layer includes silicon nitride.

18. The semiconductor device of claim 13,
wherein the bit line-side capping layer includes:
a nitrogen-free capping layer in contact with the active layer and the word line; and
a nitrogen-containing capping layer over the nitrogen-free capping layer, and
wherein the nitrogen-free capping layer is disposed between the nitrogen-containing capping layer and the active layer.

19. The semiconductor device of claim 13,
wherein the active layer includes monocrystalline silicon, and
wherein the trap-suppressing material of the capping layer and the bit line-side capping layer include nitrogen-free silicon oxide.

20. The semiconductor device of claim 1, wherein an interface between the active layer and the capping layer includes a trap-free interface.
